(19) United States
(12) Patent Application Publication
(10) Pub. No.: US 2013/0322022 A1
(43) Pub. Date: Dec. 5, 2013

(54) HEAT-DISSIPATING APPARATUS

(71) Applicants: Tung-Feng WU, Hu Kou Township (TW); Tze-Yun SUNG, Hu Kou Township (TW)

(72) Inventors: Tung-Feng WU, Hu Kou Township (TW); Tze-Yun SUNG, Hu Kou Township (TW)

(21) Appl. No.: 13/488,412

(22) Filed: Jun. 4, 2012

(51) Int. Cl. H05K 7/20

(52) U.S. Cl. 361/720

(57) ABSTRACT

The present disclosure provides a heat-dissipating apparatus for printed circuit board. The heat-dissipating apparatus adopts a ceramic device arranged between the printed circuit board and ground. Therefore, the apparatus can achieve the purpose of heat dissipation and save space of the printed circuit board and save cost of using a fan and cooling fins.

### BACKGROUND OF THE DISCLOSURE

a) Field of the Disclosure

The present disclosure relates to a heat-dissipating apparatus for a printed circuit board, which adopts a ceramic device arranged between a printed circuit board and ground, and will not affect the electrical circuit function of the printed circuit board.

b) Brief Description of the Related Art

For solving the problem of heat dissipation, conventional heat-dissipating apparatus used on the printed circuit board usually has a fan cooperating with a plurality of cooling fins, or a large size of copper plate arranged to the ground of the printed circuit board.

The present disclosure described below is a heat-dissipating apparatus that does not adopt the fan and the cooling fins, so as to save the cost of the device and reduce the weight added to the printed circuit board, and thus improve the utilizability of the circuit board.

The heat-dissipating apparatus no longer has copper plate for heat dissipation, but adopts electrical circuit arrangement that arranges a ceramic device between a heat source of a printed circuit board and ground. The ceramic device is an electrical insulator and a thermal conductor, which can achieve the purpose of heat dissipation.

The heat-dissipating apparatus adopts electrical arrangement that uses a ceramic device for dissipating heat and it will not affect the electrical circuit function of the printed circuit board.

### SUMMARY OF THE DISCLOSURE

The present disclosure is to provide a heat-dissipating apparatus, which includes a ceramic device arranged between a heat source of a printed circuit board and ground.

The heat-dissipating apparatus includes a ceramic device arranged between a heat source of a printed circuit board and ground, for dissipating the heat from the heat source of the printed circuit board to ground.

The accompanying drawings are included to provide a further understanding of the invention, and are incorporated as a part of this specification. The drawings illustrate embodiments of the invention and, together with the description, serve to explain the principles of the invention.

### BRIEF DESCRIPTION OF THE DRAWINGS

The drawings disclose illustrative embodiments of the present disclosure. They do not set forth all embodiments. Other embodiments may be used in addition or instead. Details that may be apparent or unnecessary may be omitted to save space or for more effective illustration. Conversely, some embodiments may be practiced without all of the details that are disclosed. When the same numeral appears in different drawings, it refers to the same or like components or steps.

Aspects of the disclosure may be more fully understood from the following description when read together with the accompanying drawings, which are to be regarded as illustrative in nature, and not as limiting. The drawings are not necessarily to scale, emphasis instead being placed on the principles of the disclosure.

FIG. 1 is a circuit diagram of a heat-dissipating apparatus of the present disclosure.

While certain embodiments are depicted in the drawings, one skilled in the art will appreciate that the embodiments depicted are illustrative and that variations of those shown, as well as other embodiments described herein, may be envisioned and practiced within the scope of the present disclosure.

### DETAILED DESCRIPTION OF THE INVENTION

Illustrative embodiments are now described. Other embodiments may be used in addition or instead. Details that may be apparent or unnecessary may be omitted to save space or for a more effective presentation. Conversely, some embodiments may be practiced without all of the details that are disclosed.

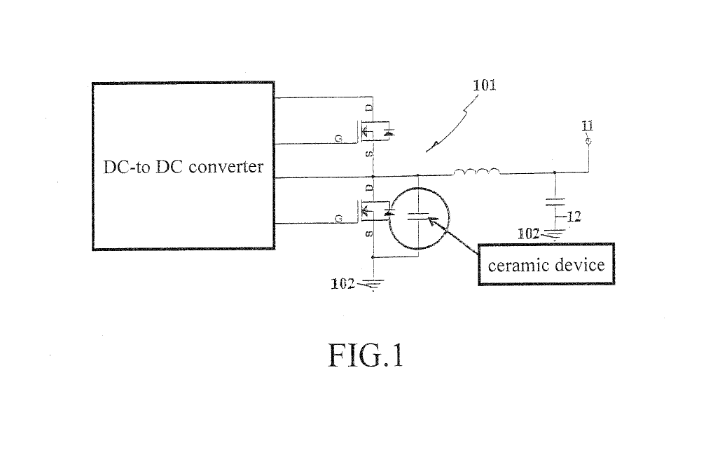

FIG. 1 is a circuit diagram of the heat-dissipating apparatus of the present disclosure. A ceramic device 100 is arranged between a heat source 101 of the circuit board and the ground 102 for dissipating heat to the ground 102. The heat source 101 includes a DC-to DC converter 10, an output electrical power 11 and an output capacitor 12.

As FIG. 1 shows, the ceramic device 100 is an electrical insulator and a thermal conductor, which is arranged at an appropriate position of the printed circuit board for replacing the conventional heat dissipating device using a fan and the cooling fins. There is no need to attach a large size copper plate on the ground of the printed circuit board. And the interference and influence of the copper plate on the electrical performance of the printed circuit board can be avoided. That is indeed a novel invention having economic value.

The scope of protection is limited solely by the claims, and such scope is intended and should be interpreted to be as broad as is consistent with the ordinary meaning of the language that is used in the claims when interpreted in light of this specification and the prosecution history that follows, and to encompass all structural and functional equivalents thereof.

What is claimed is:

1. A heat-dissipating apparatus, comprising:
a ceramic device arranged between a heat source of a printed circuit board and ground.

2. The heat-dissipating apparatus as claim 1, wherein the ceramic device is configured for dissipating the heat from the heat source of the printed circuit board to ground.
